(19) United States
(12) Patent Application Publication
(10) Pub. No.: US 2026/0239915 A1
(43) Pub. Date: Aug. 13, 2026

(54) EMISSIVITY ADJUSTMENT METHOD

(71) Applicant: SCREEN Holdings Co., Ltd., Kyoto (JP)

(72) Inventors: Akihiro KOSO, Kyoto-shi, Kyoto (JP); Takahiro KITAZAWA, Kyoto-shi, Kyoto (JP); Tomohiro UENO, Kyoto-shi, Kyoto (JP)

(21) Appl. No.: 19/160,461

(22) PCT Filed: Nov. 9, 2023
(86) PCT No.: PCT/JP2023/040351

§ 371 Date: Aug. 27, 2025

(30) Foreign Application Priority Data
Mar. 14, 2023 (JP) 2023-039325

(51) Int. Cl. H10P 72/00; H10P 74/20

(52) U.S. Cl. CPC H10P 72/0602; H10P 74/20

(57) ABSTRACT

A TC wafer including a thermocouple is heated by irradiation with light from halogen lamps, and a temperature of the TC wafer is measured by the thermocouple. The true temperature of the TC wafer measured by the thermocouple is converted into a voltage value using a voltage conversion table. A voltage value output from a radiation thermometer when the TC wafer is measured by the radiation thermometer is acquired. Emissivity is calculated based on the voltage value obtained by conversion of the true temperature of the TC wafer and the voltage value output from the radiation thermometer, and the calculated emissivity is set for the radiation thermometer. The emissivity is calculated based on the voltage value obtained by direct conversion of the true temperature of the TC wafer measured by the thermocouple, so that accurate emissivity can rapidly be calculated.

### TECHNICAL FIELD

The present invention relates to an emissivity adjustment method of adjusting emissivity set for a radiation thermometer that is installed in a thermal processing apparatus and measures a temperature of a substrate. Examples of a substrate to be processed include a semiconductor wafer, a substrate for a liquid crystal display, a substrate for a flat panel display (FPD), a substrate for an optical disc, a substrate for a magnetic disk, and a substrate for a solar cell.

### BACKGROUND ART

In a thermal processing apparatus (e.g., a lamp annealing apparatus) heating a semiconductor wafer, it is important to properly manage a wafer temperature. This requires accurate measurement of a temperature of the semiconductor wafer. As a scheme for accurately measuring the temperature of the semiconductor wafer, measurement of the wafer temperature by a thermocouple is contemplated. Direct contact of the thermocouple with the semiconductor wafer, however, not only causes contamination but also prevents transport of the semiconductor wafer by a robot, so that it is difficult to use the thermocouple for measurement of the temperature of the semiconductor wafer. A radiation thermometer that measures the temperature of the semiconductor wafer in a noncontact manner is thus widely used as a tool for measuring the temperature of the semiconductor wafer during thermal processing.

The radiation thermometer has a problem of lower measurement accuracy than the thermocouple, which measures the temperature by direct contact with a measurement target. Patent Document 1 thus discloses, while performing cycle heating processing of repeating raising and lowering of a temperature of a measurement wafer with thermocouple a plurality of times, correcting emissivity in accordance with a temperature difference between a temperature measured by a thermocouple and a temperature measured by a radiation thermometer when the temperature difference is equal to or greater than a threshold. The thermocouple can accurately measure a true temperature, so that emissivity can accurately be adjusted by correcting the emissivity with reference to the temperature measured by the thermocouple.

### PRIOR ART DOCUMENTS

### Patent Document

Patent Document 1: Japanese Patent Application Laid-Open No. 2022-73150

### SUMMARY

### Problem to be Solved by the Invention

In technology disclosed in Patent Document 1, however, the emissivity is gradually caused to match an accurate value in a plurality of separate stages while raising and lowering of the temperature of the measurement wafer are repeated the plurality of times, so that it sometimes takes time to adjust the emissivity.

The present invention has been conceived in view of the above-mentioned problem, and it is an object of the present invention to provide an emissivity adjustment method enabling rapid adjustment of emissivity set for a radiation thermometer with high accuracy.

### Means to Solve the Problem

To solve the above-mentioned problem, a first aspect of the present invention is an emissivity adjustment method of adjusting emissivity set for a radiation thermometer installed in a thermal processing apparatus, the emissivity adjustment method including: a first heating step of heating a substrate with thermocouple to an increased temperature, the substrate with thermocouple including a thermocouple; a temperature measurement step of measuring, by the thermocouple, the increased temperature of the substrate with thermocouple; a voltage value calculation step of calculating a theoretical voltage value from the temperature of the substrate with thermocouple measured by the thermocouple; a voltage value measurement step of measuring, by the radiation thermometer, the increased temperature of the substrate with thermocouple and outputting an actual voltage value from the radiation thermometer; an emissivity calculation step of calculating emissivity based on the theoretical voltage value and the actual voltage value; and an emissivity setting step of setting the calculated emissivity for the radiation thermometer.

A second aspect is the emissivity adjustment method according to the first aspect, wherein a warning is issued when the calculated emissivity falls outside a predetermined range.

A third aspect is the emissivity adjustment method according to the first or the second aspect, further including: a second heating step of heating the substrate with thermocouple to an increased temperature; and a verification step of verifying, with reference to a temperature of the substrate with thermocouple measured by the thermocouple, a temperature of the substrate with thermocouple measured by the radiation thermometer for which the emissivity has been set.

A fourth aspect is the emissivity adjustment method according to the third aspect, wherein a warning is issued when the temperature of the substrate with thermocouple measured by the radiation thermometer deviates from the temperature of the substrate with thermocouple measured by the thermocouple by a certain temperature or more.

A fifth aspect is the emissivity adjustment method according to any one of the first to the fourth aspects, wherein in the voltage value calculation step, the theoretical voltage value is calculated based on a conversion table indicating a correlation between a voltage value output from the radiation thermometer and a temperature.

A sixth aspect is the emissivity adjustment method according to the fifth aspect, wherein the conversion table indicates a correlation between a voltage value and a temperature when a black body is measured by the radiation thermometer.

A seventh aspect is the emissivity adjustment method according to any one of the first to the sixth aspects, wherein in the first heating step, the substrate with thermocouple is heated by irradiation with light from a continuous lighting lamp and is maintained at a constant temperature.

### Effects of the Invention

According to the emissivity adjustment method according to the first to the seventh aspects, the emissivity is calculated based on the theoretical voltage value calculated from the temperature of the substrate with thermocouple measured by the thermocouple and the actual voltage value obtained by measuring the substrate with thermocouple by the radiation thermometer and output from the radiation thermometer, so that the emissivity is calculated based on the voltage value obtained by direct conversion of a true temperature of the substrate with thermocouple measured by the thermocouple, and thus the emissivity set for the radiation thermometer can rapidly be adjusted with high accuracy.

Especially according to the emissivity adjustment method according to the fifth aspect, the theoretical voltage value is calculated based on the conversion table indicating the correlation between the voltage value output from the radiation thermometer and the temperature, so that the temperature of the substrate with thermocouple measured by the thermocouple can rapidly and directly be converted into the theoretical voltage value.

### BRIEF DESCRIPTION OF DRAWINGS

FIG. 1 is a longitudinal cross-sectional view illustrating a configuration of a thermal processing apparatus into which a radiation thermometer targeted for an emissivity adjustment method according to the present invention has been incorporated.

FIG. 2 is a perspective view illustrating appearance of a holder as a whole.

FIG. 3 is a plan view of a susceptor.

FIG. 4 is a cross-sectional view of the susceptor.

FIG. 5 is a plan view of a transfer mechanism.

FIG. 6 is a side view of the transfer mechanism.

FIG. 7 is a plan view illustrating arrangement of a plurality of halogen lamps.

FIG. 8 is a flowchart showing procedures for adjustment of emissivity set for an upper radiation thermometer.

FIG. 9 is a flowchart showing procedures for adjustment of the emissivity set for the upper radiation thermometer.

FIG. 10 is a plan view illustrating one example of a TC wafer mounted on the susceptor.

FIG. 11 is a diagram showing one example of a change in temperature of the TC wafer heated for adjustment of the emissivity.

FIG. 12 is a diagram showing one example of a temperature conversion table.

FIG. 13 is a diagram showing one example of a voltage conversion table.

FIG. 14 is a diagram showing a correlation between a voltage output from the upper radiation thermometer and a temperature.

### DESCRIPTION OF EMBODIMENT

An embodiment according to the present invention will be described in detail below with reference to the drawings. In description made below, expressions indicating relative or absolute positional relationships (e.g., “in one direction”, “along one direction”, “parallel”, “orthogonal”, “central”, “concentric”, and “coaxial”) not only exactly represent the positional relationships but also represent a state where an angle or a distance is changed within tolerance or to the extent that similar functions can be obtained unless otherwise noted. Expressions indicating equality (e.g., “same”, “equal”, and “homogeneous”) not only represent quantitatively exact equality but also represent a state where there is a difference within tolerance or to the extent that similar functions can be obtained unless otherwise noted. Expressions indicating shapes (e.g., “circular”, “rectangular”, and “cylindrical”) not only represent geometrically exact shapes but also represent shapes to the extent that the same level of effectiveness is obtained unless otherwise noted and may have unevenness or chamfers. An expression such as “comprising”, “equipped with”, “provided with”, “including”, or “having” a component is not an exclusive expression that excludes the presence of the other components. An expression “at least one of A, B, and C” includes “A only”, “B only”, “C only”, “any two of A, B, and C”, and “all of A, B, and C”.

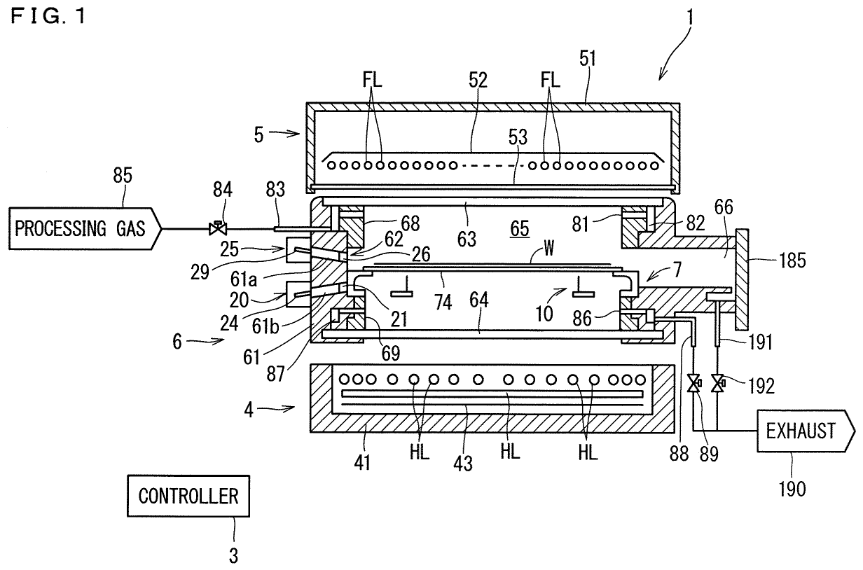

First, description will be made on a configuration of a thermal processing apparatus 1 into which a radiation thermometer targeted for an emissivity adjustment method according to the present invention has been incorporated. FIG. 1 is a longitudinal cross-sectional view illustrating the configuration of the thermal processing apparatus 1. The thermal processing apparatus 1 in FIG. 1 is a flash lamp annealing apparatus that irradiates a disk-shaped semiconductor wafer W serving as a substrate with flashes of light to heat the semiconductor wafer W. While a size of the semiconductor wafer W to be processed is not particularly limited, the semiconductor wafer W has a diameter of 300 mm or 450 mm (300 mm in the present embodiment), for example. Dimensions and the number of components are exaggerated or simplified as appropriate in FIG. 1 and the subsequent figures for ease of understanding.

The thermal processing apparatus 1 includes a chamber 6 for receiving the semiconductor wafer W, a flash heating part 5 incorporating a plurality of flash lamps FL, and a halogen heating part 4 incorporating a plurality of halogen lamps HL. The flash heating part 5 is disposed above the chamber 6, and the halogen heating part 4 is disposed below the chamber 6. The thermal processing apparatus 1 further includes a holder 7 located inside the chamber 6 and for holding the semiconductor wafer W in a horizontal orientation and a transfer mechanism 10 located inside the chamber 6 and for transferring the semiconductor wafer W between the holder 7 and an outside of the apparatus. The thermal processing apparatus 1 further includes a controller 3 that controls operating mechanisms arranged in the halogen heating part 4, the flash heating part 5, and the chamber 6 to cause the operating mechanisms to thermally process the semiconductor wafer W.

The chamber 6 is configured by attaching respective chamber windows made of quartz to a top and a bottom of a tubular chamber side portion 61. The chamber side portion 61 has a generally tubular shape having a top opening and a bottom opening, an upper chamber window 63 is attached to block the top opening, and a lower chamber window 64 is attached to block the bottom opening of the chamber side portion 61. The upper chamber window 63 forming a ceiling of the chamber 6 is a disk-shaped member made of quartz and serves as a quartz window that transmits flashes of light emitted from the flash heating part 5 therethrough into the chamber 6. The lower chamber window 64 forming a floor of the chamber 6 is also a disk-shaped member made of quartz and serves as a quartz window that transmits light emitted from the halogen heating part 4 therethrough into the chamber 6.

A reflective ring 68 and a reflective ring 69 are respectively attached to an upper portion and a lower portion of an inner wall surface of the chamber side portion 61. The reflective rings 68 and 69 are each formed to be annular. The upper reflective ring 68 is attached by being fit from above the chamber side portion 61. On the other hand, the lower reflective ring 69 is attached by being fit from below the chamber side portion 61 and fastened with screws, which are not illustrated. That is to say, the reflective rings 68 and 69 are each removably attached to the chamber side portion 61. An interior space of the chamber 6, i.e., a space surrounded by the upper chamber window 63, the lower chamber window 64, the chamber side portion 61, and the reflective rings 68 and 69, is defined as a thermal processing space 65.

The reflective rings 68 and 69 are attached to the chamber side portion 61, so that a recess 62 is formed in the inner wall surface of the chamber 6. That is to say, the recess 62 surrounded by a middle portion of the inner wall surface of the chamber side portion 61 where the reflective rings 68 and 69 are not attached, a lower end surface of the reflective ring 68, and an upper end surface of the reflective ring 69 is formed. The recess 62 is formed in the inner wall surface of the chamber 6 to be annular along a horizontal direction and surrounds the holder 7 for holding the semiconductor wafer W. The chamber side portion 61 and the reflective rings 68 and 69 are made of a metal material (e.g., stainless steel) with high strength and high heat resistance.

The chamber side portion 61 has a transport opening (throat) 66 for transport of the semiconductor wafer W into and out of the chamber 6. The transport opening 66 is openable and closable by a gate valve 185. The transport opening 66 is connected in communication with an outer peripheral surface of the recess 62. The semiconductor wafer W can thus be transported from the transport opening 66 to the thermal processing space 65 through the recess 62 and be transported from the thermal processing space 65 through the recess 62 when the gate valve 185 opens the transport opening 66. The thermal processing space 65 in the chamber 6 is an enclosed space when the gate valve 185 closes the transport opening 66.

The chamber side portion 61 further has a through hole 61a and a through hole 61b. The through hole 61a is a cylindrical hole for directing infrared light emitted from an upper surface of the semiconductor wafer W held by a susceptor 74, which will be described below, therethrough to an infrared sensor 29 of an upper radiation thermometer 25. On the other hand, the through hole 61b is a cylindrical hole for directing infrared light emitted from a lower surface of the semiconductor wafer W therethrough to an infrared sensor 24 of a lower radiation thermometer 20. The through hole 61a and the through hole 61b are inclined with respect to the horizontal direction so that an axis thereof in a direction of extension intersects a main surface of the semiconductor wafer W held by the susceptor 74. A transparent window 26 that transmits therethrough infrared light in a wavelength range measurable by the upper radiation thermometer 25 is attached to an end portion of the through hole 61a which faces the thermal processing space 65. A transparent window 21 that transmits therethrough infrared light in a wavelength range measurable by the lower radiation thermometer 20 is attached to an end portion of the through hole 61b which faces the thermal processing space 65.

A gas supply hole 81 for supplying a processing gas to the thermal processing space 65 is formed in an upper portion of an inner wall of the chamber 6. The gas supply hole 81 is formed at a position above the recess 62 and may be formed in the reflective ring 68. The gas supply hole 81 is connected in communication with a gas supply tube 83 through a buffer space 82 formed to be annular inside a side wall of the chamber 6. The gas supply tube 83 is connected to a processing gas supply source 85. A valve 84 is interposed along a path of the gas supply tube 83. When the valve 84 is opened, the processing gas is supplied from the processing gas supply source 85 to the buffer space 82. The processing gas flowing into the buffer space 82 flows to spread in the buffer space 82 having a lower fluid resistance than the gas supply hole 81 and is supplied through the gas supply hole 81 into the thermal processing space 65. Examples of the processing gas usable herein include inert gases such as nitrogen (N₂), reactive gases such as hydrogen (H₂) and ammonia (NH₃), and mixtures of these gases (a nitrogen gas in the present embodiment).

On the other hand, a gas exhaust hole 86 for exhausting gas in the thermal processing space 65 is formed in a lower portion of the inner wall of the chamber 6. The gas exhaust hole 86 is formed at a position below the recess 62 and may be formed in the reflective ring 69. The gas exhaust hole 86 is connected in communication with a gas exhaust tube 88 through a buffer space 87 formed to be annular inside the side wall of the chamber 6. The gas exhaust tube 88 is connected to an exhaust part 190. A valve 89 is interposed along a path of the gas exhaust tube 88. When the valve 89 is opened, gas in the thermal processing space 65 is exhausted from the gas exhaust hole 86 through the buffer space 87 to the gas exhaust tube 88. The gas supply hole 81 and the gas exhaust hole 86 may respectively include a plurality of gas supply holes and a plurality of gas exhaust holes arranged in a circumferential direction of the chamber 6 and may be in the form of slits. The processing gas supply source 85 and the exhaust part 190 may be mechanisms arranged in the thermal processing apparatus 1 or may be utilities in a factory in which the thermal processing apparatus 1 is installed.

A gas exhaust tube 191 for exhausting gas in the thermal processing space 65 is also connected to a distal end of the transport opening 66. The gas exhaust tube 191 is connected through a valve 192 to the exhaust part 190. By opening the valve 192, gas in the chamber 6 is exhausted through the transport opening 66.

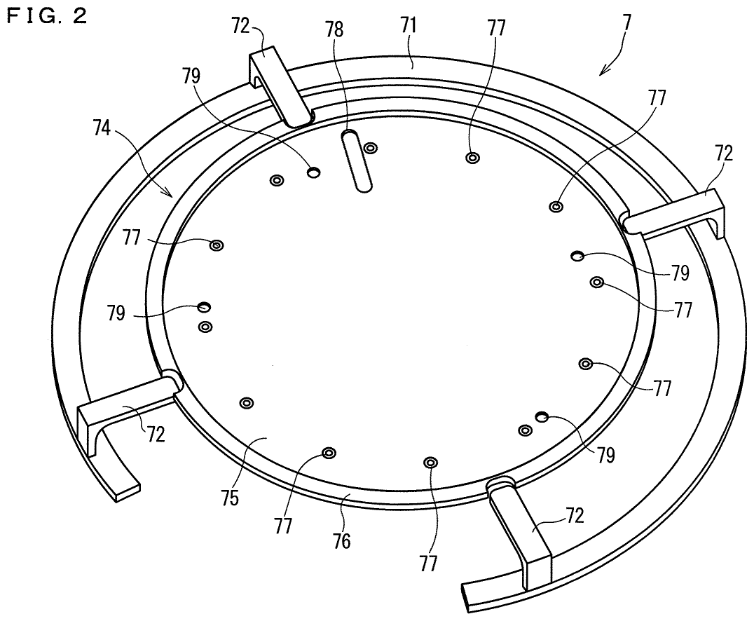

FIG. 2 is a perspective view illustrating appearance of the holder 7 as a whole. The holder 7 includes a base ring 71, connectors 72, and the susceptor 74. The base ring 71, the connectors 72, and the susceptor 74 are each made of quartz. That is to say, the holder 7 as a whole is made of quartz.

The base ring 71 is a quartz member having an arc shape that is a partially-missing annular shape. The missing portion is provided to prevent interference between transfer arms 11 of the transfer mechanism 10, which will be described below, and the base ring 71. The base ring 71 is mounted on a bottom surface of the recess 62 to be supported by a wall surface of the chamber 6 (see FIG. 1). The plurality of (four in the present embodiment) connectors 72 are arranged to stand on an upper surface of the base ring 71 along a circumferential direction of the annular shape thereof. The connectors 72 are also quartz members and are fixed to the base ring 71 by welding.

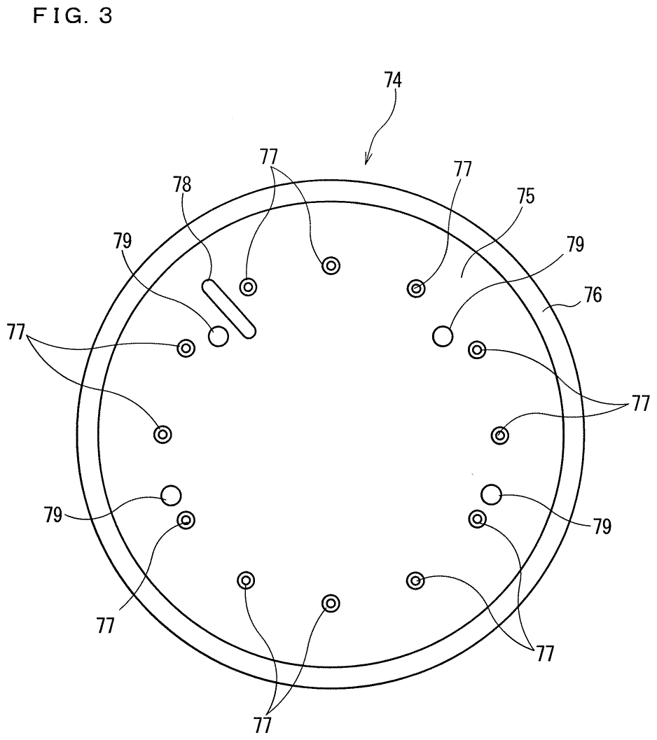

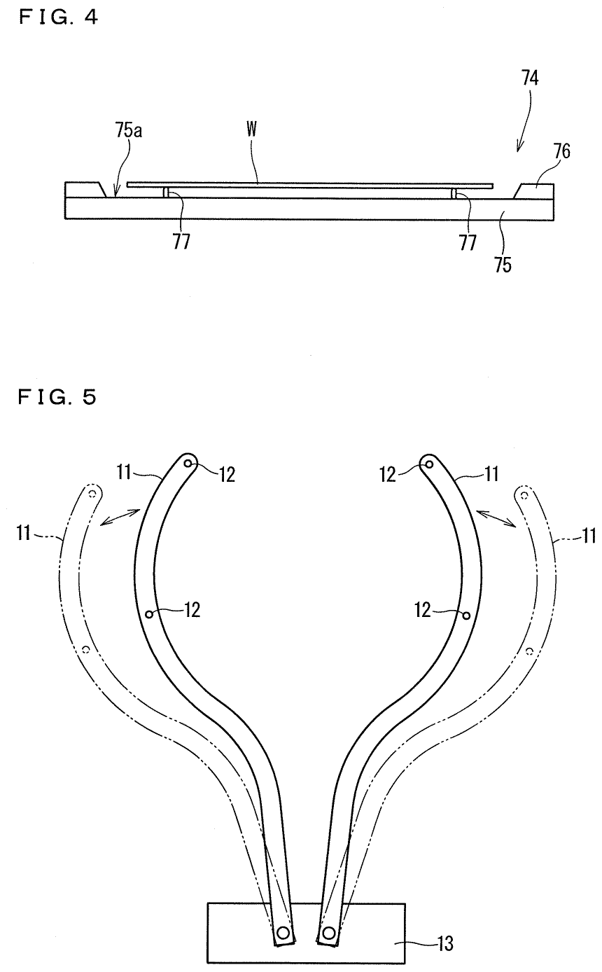

The susceptor 74 is supported by the four connectors 72 arranged on the base ring 71. FIG. 3 is a plan view of the susceptor 74. FIG. 4 is a cross-sectional view of the susceptor 74. The susceptor 74 includes a holding plate 75, a guide ring 76, and a plurality of substrate support pins 77. The holding plate 75 is a substantially circular planar member made of quartz. The holding plate 75 has a greater diameter than the semiconductor wafer W. That is to say, the holding plate 75 has a greater planar size than the semiconductor wafer W.

The guide ring 76 is installed at a periphery of an upper surface of the holding plate 75. The guide ring 76 is an annular member having an inner diameter greater than the diameter of the semiconductor wafer W. For example, the guide ring 76 has an inner diameter of 320 mm when the semiconductor wafer W has a diameter of 300 mm. An inner circumference of the guide ring 76 is a tapered surface widening upward from the holding plate 75. The guide ring 76 is made of quartz as with the holding plate 75. The guide ring 76 may be welded onto the upper surface of the holding plate 75 or may be fixed to the holding plate 75 with pins and the like processed separately. Alternatively, the holding plate 75 and the guide ring 76 may be processed as an integral member.

A region of the upper surface of the holding plate 75 inward of the guide ring 76 is a planar holding surface 75a for holding the semiconductor wafer W. The plurality of substrate support pins 77 are arranged to stand on the holding surface 75a of the holding plate 75. In the present embodiment, a total of 12 substrate support pins 77 are arranged at 300 intervals to stand along a circumference of a circle concentric with an outer circumference of the holding surface 75a (the inner circumference of the guide ring 76). A diameter of the circle along which the 12 substrate support pins 77 are arranged (a distance between opposite substrate support pins 77) is smaller than the diameter of the semiconductor wafer W and is 270 mm to 280 mm (270 mm in the present embodiment) when the semiconductor wafer W has a diameter of 300 mm. The substrate support pins 77 are each made of quartz. The plurality of substrate support pins 77 may be arranged on the upper surface of the holding plate 75 by welding or may processed to be integral with the holding plate 75.

Referring back to FIG. 2, the four connectors 72 arranged to stand on the base ring 71 and the periphery of the holding plate 75 of the susceptor 74 are fixed by welding. That is to say, the susceptor 74 and the base ring 71 are fixedly connected by the connectors 72. The base ring 71 of the holder 7 as described above is supported by the wall surface of the chamber 6 to attach the holder 7 to the chamber 6. When the holder 7 is attached to the chamber 6, the holding plate 75 of the susceptor 74 is in the horizontal orientation (in an orientation in which a normal thereto coincides with a vertical direction). That is to say, the holding surface 75a of the holding plate 75 is a horizontal surface.

The semiconductor wafer W transported into the chamber 6 is mounted and held on the susceptor 74 of the holder 7 attached to the chamber 6 in the horizontal orientation. In this case, the semiconductor wafer W is supported by the 12 substrate support pins 77 arranged to stand on the holding plate 75 to be held by the susceptor 74. More strictly, upper ends of the 12 substrate support pins 77 are in contact with the lower surface of the semiconductor wafer W to support the semiconductor wafer W. The 12 substrate support pins 77 have a uniform height (distance from the upper ends of the substrate support pins 77 to the holding surface 75a of the holding plate 75) and thus can support the semiconductor wafer W in the horizontal orientation.

The semiconductor wafer W is to be supported by the plurality of substrate support pins 77 while being spaced apart from the holding surface 75a of the holding plate 75 by a predetermined distance. The thickness of the guide ring 76 is greater than the height of each of the substrate support pins 77. Misalignment in the horizontal direction of the semiconductor wafer W supported by the plurality of substrate support pins 77 is thus prevented by the guide ring 76.

As illustrated in FIGS. 2 and 3, the holding plate 75 of the susceptor 74 has an opening 78 vertically extending through the holding plate 75. The opening 78 is formed for the lower radiation thermometer 20 to receive light (infrared light) radiated from the lower surface of the semiconductor wafer W. That is to say, the lower radiation thermometer 20 receives light radiated from the lower surface of the semiconductor wafer W through the opening 78 and the transparent window 21 attached to the through hole 61a of the chamber side portion 61 and measures a temperature of the semiconductor wafer W. The holding plate 75 of the susceptor 74 further has four through holes 79 through which lift pins 12 of the transfer mechanism 10, which will be described below, penetrate for transfer of the semiconductor wafer W.

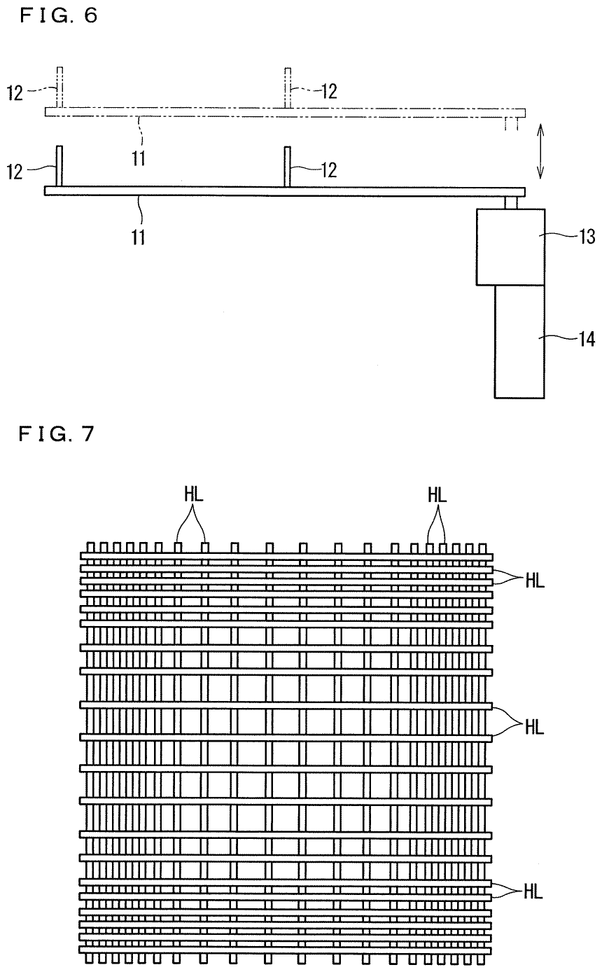

FIG. 5 is a plan view of the transfer mechanism 10. FIG. 6 is a side view of the transfer mechanism 10. The transfer mechanism 10 includes two transfer arms 11. The transfer arms 11 have an arc shape substantially along the recess 62 formed to be annular. Two lift pins 12 are arranged to stand on each of the transfer arms 11. The transfer arms 11 and the lift pins 12 are each made of quartz. The transfer arms 11 are each pivotable by a horizontal movement mechanism 13. The horizontal movement mechanism 13 horizontally moves the pair of transfer arms 11 between a transfer operation position (a position in solid lines in FIG. 5) where the semiconductor wafer W is transferred to and from the holder 7 and a withdrawal position (a position in alternate long and short dashed lines in FIG. 5) where the pair of transfer arms 11 does not overlap the semiconductor wafer W held by the holder 7 in plan view. The horizontal movement mechanism 13 may pivot the respective transfer arms 11 by separate motors or may pivot the transfer arms 11 in conjunction with each other using a link mechanism by a single motor.

The pair of transfer arms 11 is moved upward and downward by a lift mechanism 14 along with the horizontal movement mechanism 13. When the lift mechanism 14 moves the pair of transfer arms 11 upward at the transfer operation position, a total of four lift pins 12 pass through the through holes 79 (see FIGS. 2 and 3) formed in the susceptor 74, and upper ends of the lift pins 12 protrude from an upper surface of the susceptor 74. On the other hand, when the lift mechanism 14 moves the pair of transfer arms 11 downward at the transfer operation position to draw the lift pins 12 from the through holes 79, and the horizontal movement mechanism 13 moves the pair of transfer arms 11 to open the transfer arms 11, the transfer arms 11 are moved to the withdrawal position. The withdrawal position of the pair of transfer arms 11 is directly above the base ring 71 of the holder 7. Since the base ring 71 is mounted on the bottom surface of the recess 62, the withdrawal position of the transfer arms 11 is inside the recess 62. An exhaust mechanism, which is not illustrated, is disposed near a position at which a drive unit (the horizontal movement mechanism 13 and the lift mechanism 14) of the transfer mechanism 10 is disposed to discharge an atmosphere around the drive unit of the transfer mechanism 10 to an outside of the chamber 6.

Referring back to FIG. 1, the flash heating part 5 disposed above the chamber 6 includes, within a housing 51, a light source including a plurality of (30 in the present embodiment) xenon flash lamps FL and a reflector 52 disposed to cover the light source from above. A lamp light radiation window 53 is attached to the bottom of the housing 51 of the flash heating part 5. The lamp light radiation window 53 forming a floor of the flash heating part 5 is a plate-like quartz window made of quartz. The flash heating part 5 is installed above the chamber 6, so that the lamp light radiation window 53 opposes the upper chamber window 63. The flash lamps FL irradiate the thermal processing space 65 with flashes of light from above the chamber 6 through the lamp light radiation window 53 and the upper chamber window 63.

The plurality of flash lamps FL are each a rod-like lamp having an elongated cylindrical shape and are in planar arrangement so that longitudinal directions thereof are parallel to one another along the main surface of the semiconductor wafer W held by the holder 7 (i.e., along the horizontal direction). A plane formed by arrangement of the flash lamps FL is thus a horizontal plane. A region in which the plurality of flash lamps FL are arranged is greater than a planar size of the semiconductor wafer W.

Each of the xenon flash lamps FL includes a rod-like glass tube (discharge tube) in which a xenon gas is enclosed and which includes, at opposite ends thereof, an anode and a cathode connected to a capacitor and a trigger electrode disposed on an outer circumferential surface of the glass tube. The xenon gas is electrically an insulator, so that electricity does not flow through the glass tube in a normal state even if electric charge is accumulated in the capacitor. When a high voltage is applied to the trigger electrode to cause electrical breakdown, however, electricity stored in the capacitor instantaneously flows through the glass tube, and light is emitted by excitation of atoms or molecules of xenon at the time. In such a xenon flash lamp FL, electrostatic energy stored in advance in the capacitor is converted into an extremely short light pulse of 0.1 ms to 100 ms, so that the xenon flash lamp FL has a feature of being capable of emitting extremely intense light compared with a continuous lighting light source, such as a halogen lamp HL. That is to say, the flash lamp FL is a pulsed light emitting lamp momentarily emitting light in an extremely short time of less than one second. A light emitting time of the flash lamp FL is adjustable by a coil constant of a lamp power supply to supply power to the flash lamp FL.

The reflector 52 is disposed above the plurality of flash lamps FL to cover the flash lamps FL as a whole. A basic function of the reflector 52 is to reflect flashes of light emitted from the plurality of flash lamps FL toward the thermal processing space 65. The reflector 52 is formed of an aluminum alloy plate and has a surface (a surface facing the flash lamps FL) having been roughened by blasting.

The halogen heating part 4 disposed below the chamber 6 incorporates the plurality of (40 in the present embodiment) halogen lamps HL within a housing 41. The halogen heating part 4 irradiates the thermal processing space 65 with light from below the chamber 6 through the lower chamber window 64 using the plurality of halogen lamps HL to heat the semiconductor wafer W.

FIG. 7 is a plan view illustrating arrangement of the plurality of halogen lamps HL. The 40 halogen lamps HL are arranged separately in two tiers. In an upper tier closer to the holder 7, 20 halogen lamps HL are arranged, and, in a lower tier farther from the holder 7 than the upper tier is, 20 halogen lamps HL are arranged. The halogen lamps HL are each a rod-like lamp having an elongated cylindrical shape. The 20 halogen lamps HL in each of the upper and lower tiers are arranged so that longitudinal directions thereof are parallel to one another along the main surface of the semiconductor wafer W held by the holder 7 (i.e., along the horizontal direction). A plane formed by arrangement of the halogen lamps HL in each of the upper and lower tiers is thus a horizontal plane.

As illustrated in FIG. 7, the halogen lamps HL arranged in each of the upper and lower tiers are denser in a region opposing the periphery of the semiconductor wafer W held by the holder 7 than in a region opposing a central portion of the semiconductor wafer W held by the holder 7. That is to say, the halogen lamps HL arranged in each of the upper and lower tiers have a shorter pitch at a periphery than in a central portion of lamp arrangement. The periphery of the semiconductor wafer W at which the temperature is likely to decrease during heating by irradiation with light from the halogen heating part 4 can thus be irradiated with a greater amount of light.

The halogen lamps HL are arranged so that the halogen lamps HL in the upper tier and the halogen lamps HL in the lower tier intersect each other in a grid. That is to say, a total of 40 halogen lamps HL are arranged so that the longitudinal directions of the 20 halogen lamps HL arranged in the upper tier and the longitudinal directions of the 20 halogen lamps HL arranged in the lower tier are orthogonal to each other.

Each of the halogen lamps HL is a filament light source making a filament disposed within a glass tube incandescent by allowing a current to pass therethrough to thereby emit light. Gas obtained by introducing traces of halogen elements (iodide, bromine, and the like) into an inert gas, such as nitrogen and argon, is enclosed in the glass tube. Introduction of halogen elements allows for setting the temperature of the filament to a high temperature while suppressing breakage of the filament. The halogen lamp HL thus has properties of having a longer life and being capable of continuously emitting intense light compared with a typical incandescent lamp. That is to say, the halogen lamp HL is a continuous lighting lamp continuously emitting light for at least one second or more. The halogen lamps HL have long lives as they are rod-like lamps and have excellent radiation efficiency toward the semiconductor wafer W above the halogen lamps HL by being arranged along the horizontal direction.

Also in the housing 41 of the halogen heating part 4, a reflector 43 is disposed below the halogen lamps HL arranged in two tiers (FIG. 1). The reflector 43 reflects light emitted from the plurality of halogen lamps HL toward the thermal processing space 65.

As illustrated in FIG. 1, two radiation thermometers, that is, the upper radiation thermometer 25 and the lower radiation thermometer 20 are provided to the chamber 6. The lower radiation thermometer 20 is disposed obliquely below the semiconductor wafer W held by the susceptor 74. The lower radiation thermometer 20 receives infrared light radiated from the lower surface of the semiconductor wafer W through the opening 78 as a cutout formed in the susceptor 74 and measures a temperature on the lower surface.

On the other hand, the upper radiation thermometer 25 is disposed obliquely above the semiconductor wafer W held by the susceptor 74. The upper radiation thermometer 25 receives infrared light radiated from the upper surface of the semiconductor wafer W and measures a temperature on the upper surface. The infrared sensor 29 of the upper radiation thermometer 25 incorporates a photovoltaic light-receiving element (not illustrated) to respond to a rapid change in temperature on the upper surface of the semiconductor wafer W at the moment when the upper surface is irradiated with a flash of light. The photovoltaic light-receiving element is an element that generates electromotive force due to a photoelectric effect when receiving light and is formed of InSb (indium antimonide), for example. The photovoltaic light-receiving element generates higher electromotive force as a temperature of a light emitter of the received infrared light increases.

While a conventional photoconductive element has a poor SN ratio especially in a low frequency range, the photovoltaic element exhibits good noise characteristics even in the low frequency range. That is to say, the upper radiation thermometer 25 in which the photovoltaic light-receiving element is used is characterized by both fast response and good noise characteristics in the low frequency range. While the photoconductive element is required to be cooled below freezing to obtain a high sensitivity, the photovoltaic element can obtain a sufficient sensitivity at a room temperature without cooling. Furthermore, the upper radiation thermometer 25 is not required to include an optical chopper and is also not required to include a differentiating circuit. The absence of the differentiating circuit enables measurement of the temperature of the semiconductor wafer W during preheating during which the change in temperature is slow. Thus, by using the upper radiation thermometer 25 including the photovoltaic light-receiving element, a surface temperature of the semiconductor wafer W can be measured with a simple configuration both during preheating by irradiation with light from the halogen lamps HL and during irradiation with flashes of light from the flash lamps FL.

The controller 3 controls the above-mentioned various operation mechanisms of the thermal processing apparatus 1. The controller 3 has a similar hardware configuration to a typical computer. That is to say, the controller 3 includes a CPU as a circuit to perform various types of arithmetic processing, ROM as read-only memory to store a basic program, RAM as read/write memory to store various pieces of information, and a storage (e.g., a magnetic disk or an SSD) to store control software, data, and the like. The CPU of the controller 3 executes a predetermined processing program to proceed with processing performed by the thermal processing apparatus 1.

In addition to the above-mentioned configuration, the thermal processing apparatus 1 includes various cooling structures to prevent an excessive increase in temperature of the halogen heating part 4, the flash heating part 5, and the chamber 6 caused by thermal energy generated by the halogen lamps HL and the flash lamps FL during thermal processing of the semiconductor wafer W. For example, a water-cooled tube (not illustrated) is disposed in a wall body of the chamber 6. The halogen heating part 4 and the flash heating part 5 each have an air-cooled structure in which a gas flow is formed to exhaust heat. Air is supplied to a gap between the upper chamber window 63 and the lamp light radiation window 53 to cool the flash heating part 5 and the upper chamber window 63.

Processing operation performed by the thermal processing apparatus 1 will be described next. Typical thermal processing operation performed on a normal semiconductor wafer (product wafer) W to be a product will herein be described first. The procedures of processing of the semiconductor wafer W described below proceed by the controller 3 controlling each operation mechanism of the thermal processing apparatus 1.

First, prior to processing of the semiconductor wafer W, the valve 84 for supply of gas is opened, and the valve 89 for exhaust of gas is opened, so that the supply and exhaust of gas into and out of the chamber 6 start. When the valve 84 is opened, the nitrogen gas is supplied through the gas supply hole 81 into the thermal processing space 65. When the valve 89 is opened, gas within the chamber 6 is exhausted through the gas exhaust hole 86. This allows the nitrogen gas supplied from an upper portion of the thermal processing space 65 in the chamber 6 to flow downward and to be exhausted from a lower portion of the thermal processing space 65.

Gas within the chamber 6 is exhausted also through the transport opening 66 by opening the valve 192. Furthermore, the exhaust mechanism, which is not illustrated, exhausts an atmosphere around the drive unit of the transfer mechanism 10. The nitrogen gas is continuously supplied into the thermal processing space 65 during thermal processing of the semiconductor wafer W in the thermal processing apparatus 1, and the amount of the supplied nitrogen gas is changed as appropriate in accordance with a processing step.

The gate valve 185 is then opened to open the transport opening 66, and a transport robot outside the apparatus transports the semiconductor wafer W to be processed through the transport opening 66 into the thermal processing space 65 of the chamber 6. In this case, an atmosphere outside the apparatus might be entrained by transport of the semiconductor wafer W, but the nitrogen gas is continuously supplied to the chamber 6, so that an outward flow of the nitrogen gas through the transport opening 66 and such entrainment of the outside atmosphere can be minimized.

The semiconductor wafer W transported by the transport robot is moved to a position directly above the holder 7 and is stopped. The pair of transfer arms 11 of the transfer mechanism 10 horizontally moves from the withdrawal position to the transfer operation position and moves upward, so that the lift pins 12 pass through the through holes 79 to protrude from the upper surface of the holding plate 75 of the susceptor 74 and receive the semiconductor wafer W. In this case, the lift pins 12 are moved above the upper ends of the substrate support pins 77.

After the semiconductor wafer W is mounted on the lift pins 12, the transport robot leaves the thermal processing space 65, and the transport opening 66 is closed by the gate valve 185. The pair of transfer arms 11 moves downward, so that the semiconductor wafer W is transferred from the transfer mechanism 10 to the susceptor 74 of the holder 7 and is held in the horizontal orientation from below. The semiconductor wafer W is held by the susceptor 74 while being supported by the plurality of substrate support pins 77 arranged to stand on the holding plate 75. The semiconductor wafer W is held by the holder 7 with the front surface as a surface to be processed facing upward. There is the predetermined distance between a back surface (a main surface opposite the front surface) of the semiconductor wafer W supported by the plurality of substrate support pins 77 and the holding surface 75a of the holding plate 75. The pair of transfer arms 11 having moved downward to a position below the susceptor 74 is withdrawn by the horizontal movement mechanism 13 to the withdrawal position, that is, to the inside of the recess 62.

After the semiconductor wafer W is held in the horizontal orientation from below by the susceptor 74 of the holder 7 made of quartz, the 40 halogen lamps HL of the halogen heating part 4 are simultaneously turned on to start preheating (assist heating). Halogen light emitted from the halogen lamps HL is transmitted through the lower chamber window 64 and the susceptor 74 each made of quartz and is applied to the lower surface of the semiconductor wafer W. By being irradiated with light from the halogen lamps HL, the semiconductor wafer W is preheated to an increased temperature. The transfer arms 11 of the transfer mechanism 10 are withdrawn to the inside of the recess 62 and thus do not interfere with heating by the halogen lamps HL.

The temperature of the semiconductor wafer W increased by irradiation with light from the halogen lamps HL is measured by the lower radiation thermometer 20. The measured temperature of the semiconductor wafer W is transmitted to the controller 3. The controller 3 controls output of the halogen lamps HL while monitoring the temperature of the semiconductor wafer W increased by irradiation with light from the halogen lamps HL to determine whether it has reached a predetermined preheat temperature Ta. That is to say, the controller 3 performs feedback control of output of the halogen lamps HL based on a value measured by the lower radiation thermometer 20 so that the temperature of the semiconductor wafer W becomes the preheat temperature Ta. The lower radiation thermometer 20 serves as a control temperature sensor to control output of the halogen lamps HL during preheating of the semiconductor wafer W.

After the temperature of the semiconductor wafer W reaches the preheat temperature Ta, the controller 3 maintains the semiconductor wafer W at the preheat temperature Ta for a while. Specifically, at a point in time when the temperature of the semiconductor wafer W measured by the lower radiation thermometer 20 reaches the preheat temperature Ta, the controller 3 adjusts output of the halogen lamps HL to maintain the semiconductor wafer W substantially at the preheat temperature Ta.

Such preheating by the halogen lamps HL allows for a uniform increase in temperature of the semiconductor wafer W as a whole to the preheat temperature Ta. At a stage of preheating by the halogen lamps HL, the temperature at the periphery of the semiconductor wafer W where heat is more likely to be dissipated tends to be lower than the temperature in the central portion of the semiconductor wafer W, but the halogen lamps HL of the halogen heating part 4 are denser in the region opposing the periphery of the semiconductor wafer W than in the region opposing the central portion of the semiconductor wafer W. The periphery of the semiconductor wafer W where heat is likely to be dissipated is thus irradiated with a greater amount of light to make in-plane temperature distribution of the semiconductor wafer W at the preheating stage uniform.

At a point in time when a predetermined time has elapsed since the temperature of the semiconductor wafer W reaching the preheat temperature Ta, the flash lamps FL of the flash heating part 5 irradiate the front surface of the semiconductor wafer W held by the susceptor 74 with flashes of light. In this case, some flashes of light radiated from the flash lamps FL are directly directed toward the inside of the chamber 6, and other flashes of light radiated from the flash lamps FL are once reflected by the reflector 52 and then directed toward the inside of the chamber 6, so that the semiconductor wafer W is flash heated by irradiation with these flashes of light.

Flash heating is performed by irradiation with flashes of light from the flash lamps FL, so that the temperature on the front surface of the semiconductor wafer W can be increased in a short time. That is to say, flashes of light emitted from the flash lamps FL are intense flashes of light having an extremely short irradiation time of approximately 0.1 ms or more and 100 ms or less obtained by converting electrostatic energy stored in advance in the capacitor into an extremely short light pulse. The temperature on the front surface of the semiconductor wafer W flash heated by irradiation with flashes of light from the flash lamps FL momentarily increases to a processing temperature Tp of 1000° C. or more and then rapidly decreases. The temperature on the front surface of the semiconductor wafer W rapidly changed by irradiation with flashes of light may be measured by the upper radiation thermometer 25.

After a predetermined time has elapsed since the end of the flash heating processing, the halogen lamps HL are turned off. The temperature of the semiconductor wafer W thus rapidly decreases from the preheat temperature Ta. The temperature of the semiconductor wafer W being decreasing is measured by the lower radiation thermometer 20, and a result of measurement is transmitted to the controller 3. The controller 3 monitors the temperature of the semiconductor wafer W to determine whether it has decreased to a predetermined temperature based on the result of measurement performed by the lower radiation thermometer 20. After the temperature of the semiconductor wafer W decreases to or below a predetermined temperature, the pair of transfer arms 11 of the transfer mechanism 10 horizontally moves again from the withdrawal position to the transfer operation position and moves upward, so that the lift pins 12 protrude from the upper surface of the susceptor 74 and receive the semiconductor wafer W after thermal processing from the susceptor 74. Then, the transport opening 66 having been closed by the gate valve 185 is opened, and the semiconductor wafer W mounted on the lift pins 12 are transported from the chamber 6 by the transport robot outside the apparatus to complete heating of the semiconductor wafer W.

The thermal processing apparatus 1 includes the upper radiation thermometer 25 and the lower radiation thermometer 20 that each measure the temperature of the semiconductor wafer W during thermal processing. Emissivity of the semiconductor wafer W as a target of temperature measurement is set for each of the upper radiation thermometer 25 and the lower radiation thermometer 20 as noncontact temperature sensors, and, if there is an error in the set emissivity, the upper radiation thermometer 25 and the lower radiation thermometer 20 cannot accurately measure the temperature of the semiconductor wafer W. In the present embodiment, the emissivity set for the upper radiation thermometer 25 is adjusted as described below.

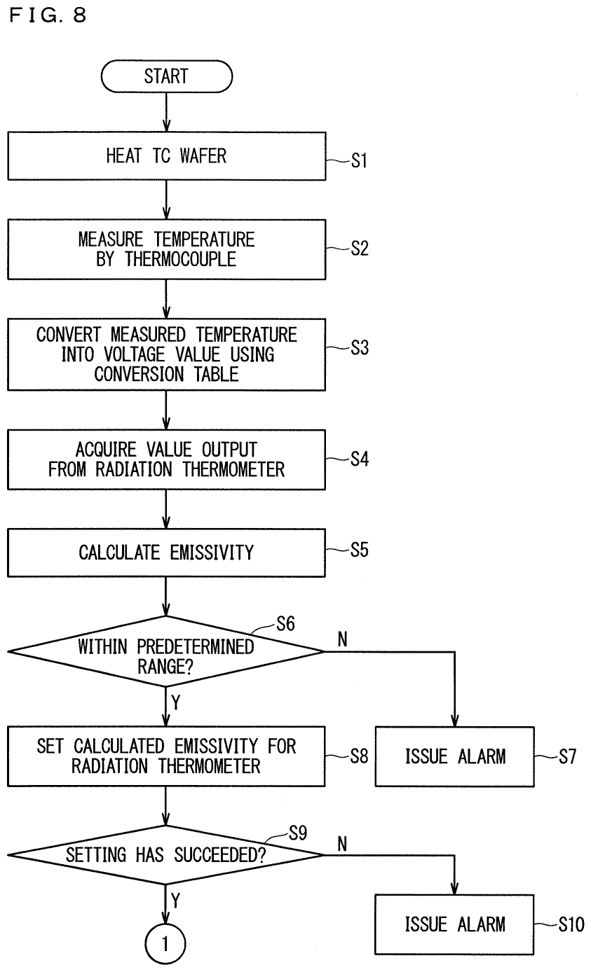

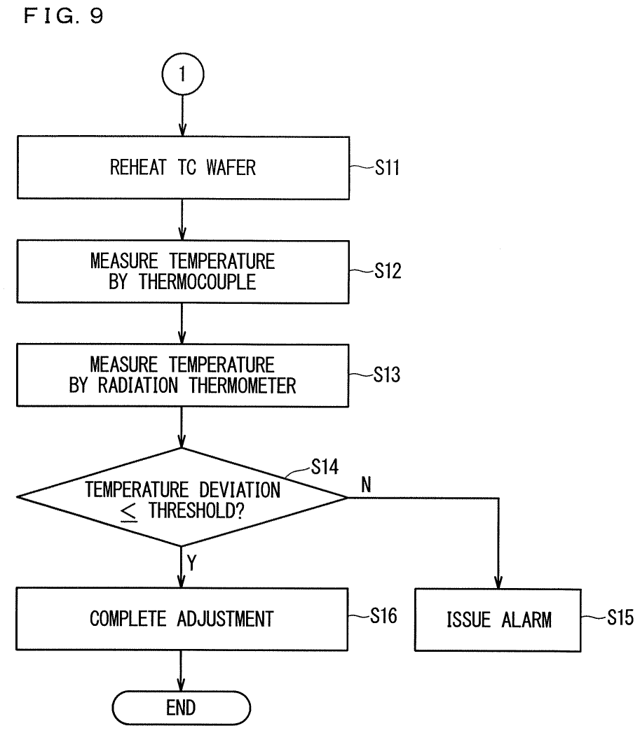

FIGS. 8 and 9 are flowcharts showing procedures for adjustment of the emissivity set for the upper radiation thermometer 25. The emissivity is adjusted, for example, before the start of processing of a lot. As a work on preparation for processing of adjusting the emissivity, a TC wafer 9 including a thermocouple (a substrate with thermocouple) is transported into the chamber 6 and is mounted on the susceptor 74. The TC wafer 9 is a disk-shaped substrate of silicon that is the same as the normal semiconductor wafer W except that TC wafer 9 includes the thermocouple. The TC wafer 9 including the thermocouple cannot be transported by the transport robot and thus is manually transported into the chamber 6 and mounted on the susceptor 74.

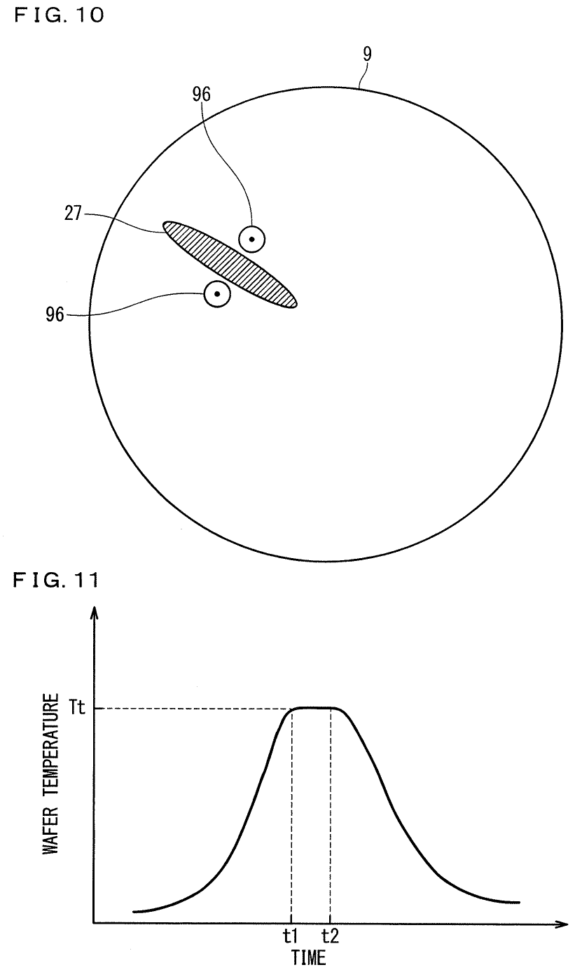

FIG. 10 is a plan view illustrating one example of the TC wafer 9 mounted on the susceptor 74. The upper radiation thermometer 25 is disposed obliquely above the TC wafer 9 held by the susceptor 74, so that a measurement region (field of view) 27 of the upper radiation thermometer 25 on an upper surface of the TC wafer 9 has an elliptical shape elongated in a direction of a major axis as illustrated in FIG. 10. The TC wafer 9 includes two temperature measurement portions 96 of the thermocouple near the measurement region 27 of the upper radiation thermometer 25. While the TC wafer 9 has temperature distribution, the temperature measurement portions 96 are located near the measurement region 27, so that the thermocouple can generally accurately measure the temperature in the measurement region 27 of the upper radiation thermometer 25. The two temperature measurement portions 96 are preferably located to sandwich the measurement region 27 therebetween as illustrated in FIG. 10. That is to say, the two temperature measurement portions 96 are preferably located so that a midpoint between the temperature measurement portions 96 is located within the measurement region 27.

After the TC wafer 9 is mounted on the susceptor 74, the TC wafer 9 is heated to an increased temperature (step S1). Specifically, the TC wafer 9 is heated by irradiation with light from the halogen lamps HL. In this case, the controller 3 controls output of the halogen lamps HL according to a temperature adjustment recipe for adjustment of the emissivity prepared in advance to heat the TC wafer 9. FIG. 11 is a diagram showing one example of a change in temperature of the TC wafer 9 heated for adjustment of the emissivity. In the example of FIG. 11, after the temperature of the TC wafer 9 is increased to a target temperature Tt by irradiation with light from the halogen lamps HL, the TC wafer 9 is maintained at the target temperature Tt from time t1 to time t2. That is to say, a soak period during which the TC wafer 9 is maintained at a constant temperature is provided. After the soak period, output of the halogen lamps HL is reduced to decrease the temperature of the TC wafer 9 from the target temperature Tt.

The temperature of the TC wafer 9 is measured by the thermocouple during the soak period from the time t1 to the time t2 (step S2). As a value of the temperature of the TC wafer 9 measured by the thermocouple, an average value of the measured temperature in the two temperature measurement portions 96 is preferably used. The temperature in the measurement region 27 of the upper radiation thermometer 25 can thus accurately be measured by the thermocouple. The value of the temperature measured by the thermocouple is a true temperature of the TC wafer 9 being heated.

Next, the value of the temperature of the TC wafer 9 measured by the thermocouple is converted into a voltage value using a conversion table (step S3). The upper radiation thermometer 25 is provided with a temperature conversion table 110 to convert a voltage value of electromotive force generated in the light-receiving element into a temperature. When the upper radiation thermometer 25 receives infrared light from a measurement target, electromotive force in accordance with intensity of the infrared light is generated in the light-receiving element due to the photoelectric effect. The upper radiation thermometer 25 converts a voltage value of the electromotive force into a temperature based on the temperature conversion table 110 to obtain a temperature of the measurement target.

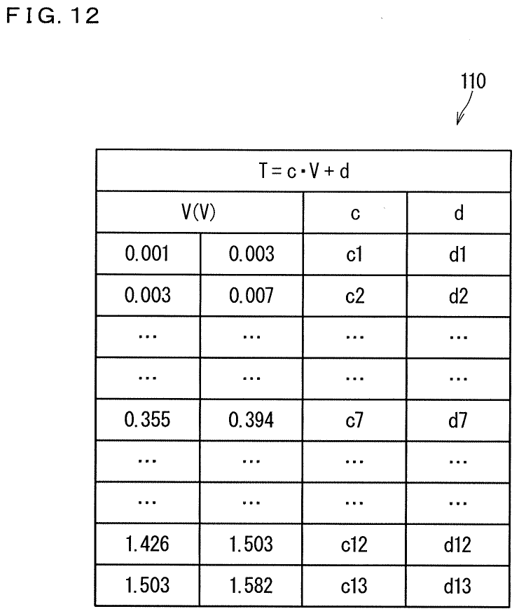

FIG. 12 is a diagram showing one example of the temperature conversion table 110. The temperature conversion table 110 is a table to obtain a temperature T from a voltage V of electromotive force based on an equation (1):

$$\begin{matrix}[ Math 1 ] & \\ T = c \cdot V + d & ( 1 )\end{matrix}$$

In the temperature conversion table 110 and the equation (1), c is a coefficient, and d is a constant. In the temperature conversion table 110, however, the coefficient c and the constant d are not completely fixed values but values varying depending on the voltage V. For example, when the voltage V of the electromotive force output from the light-receiving element of the upper radiation thermometer 25 is 0.003 V to 0.007 V, the coefficient c is c2, and the constant d is d2. When the voltage V output from the upper radiation thermometer 25 is 0.355 V to 0.394 V, the coefficient c is c7, and the constant d is d7. That is to say, in the temperature conversion table 110, a mathematical relationship between the voltage V and the temperature T is linear in each of sections obtained by division in accordance with the voltage V output from the upper radiation thermometer 25.

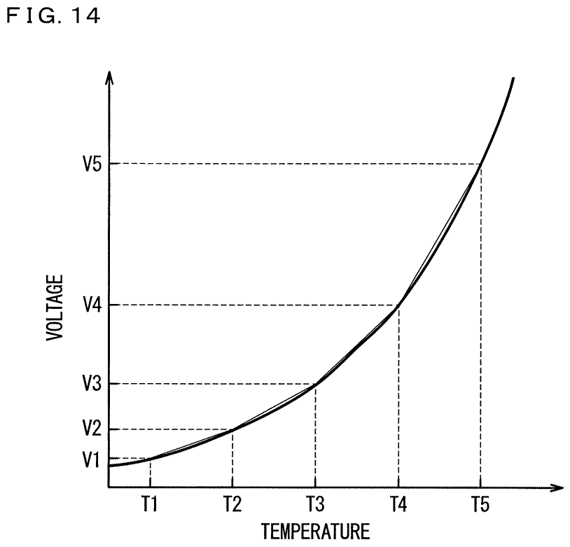

FIG. 14 is a diagram showing a correlation between the voltage V output from the upper radiation thermometer 25 and the temperature T. In the figure, the vertical axis represents the voltage V output from the upper radiation thermometer 25, and the horizontal axis represents the temperature T of the measurement target. As shown in FIG. 14, the mathematical relationship between the voltage V output from the upper radiation thermometer 25 and the temperature T is not linear. It is difficult to tabulate the nonlinear relationship between the voltage V and the temperature T as it is. The nonlinear relationship between the voltage V and the temperature T is thus divided into a plurality of small sections, and a linear fit of the relationship between the voltage V and the temperature T is performed in each of the small sections to facilitate tabulation. Division into the plurality of small sections can reduce an error between a value obtained by the linear fit and an actual value. The temperature conversion table 110 is a table prepared based on such a concept, and the coefficient c and the constant d are respectively a slope and an intercept of an approximate straight line in each of the small sections.

A principle of temperature measurement by the upper radiation thermometer 25 is that the temperature T of the measurement target is obtained from the voltage V of the electromotive force generated in the light-receiving element using the temperature conversion table 110. For example, when the voltage V of the electromotive force generated in the light-receiving element during measurement of the measurement target by the upper radiation thermometer 25 is 0.364 V, the temperature T of the measurement target is obtained from the equation (1) where the coefficient c is c7 and the constant d is d7.

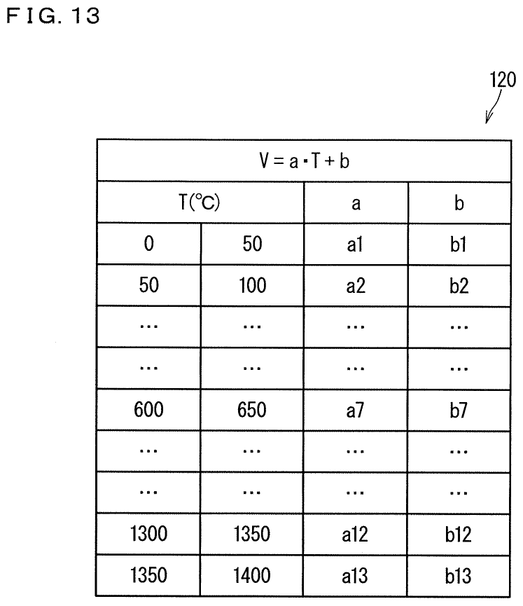

FIG. 13 is a diagram showing one example of a voltage conversion table 120. As described above, by performing the linear fit of the relationship between the voltage V and the temperature T in each of the small sections, the temperature T becomes a linear function of the voltage V as shown in the equation (1). This means that the voltage V also becomes a linear function of the temperature T. The voltage conversion table 120 is a table to obtain the voltage V from the temperature T based on an equation (2), in which the voltage V is represented by the linear function of the temperature T:

$$\begin{matrix}[ Math 2 ] & \\ V = a \cdot T + b & ( 2 )\end{matrix}$$

In the voltage conversion table 120 and the equation (2), a is a coefficient, and b is a constant. As in the temperature conversion table 110, however, the coefficient a and the constant b are not completely fixed values but values varying depending on the temperature T. For example, when the temperature T of the measurement target measured by the upper radiation thermometer 25 is 50° C. to 100° C., the coefficient a is a2, and the constant b is b2. When the temperature T of the measurement target is 600° C. to 650° C., the coefficient a is a7, and the constant b is b7. As in the temperature conversion table 110, the mathematical relationship between the temperature T and the voltage V is linear in each of sections obtained by division in accordance with the temperature T of the measurement target in the voltage conversion table 120. The voltage conversion table 120 also indicates a correlation obtained by dividing the nonlinear relationship between the voltage V and the temperature T into a plurality of small sections and performing the linear fit of the relationship in each of the small sections, and the coefficient a and the constant b are respectively a slope and an intercept of an approximate straight line in each of the small sections.

While the temperature conversion table 110 is a table to convert the voltage V into the temperature T, whereas the voltage conversion table 120 is a table to convert the temperature T into the voltage V, both the tables are equivalent based on the correlation between the voltage V and the temperature T as shown in FIG. 14. The temperature conversion table 110 and the voltage conversion table 120, however, each indicate the correlation between the voltage V and the temperature T when a black body (emissivity=1) as the measurement target is measured by the upper radiation thermometer 25. When the temperature of the semiconductor wafer W is measured by the upper radiation thermometer 25, the temperature T of the semiconductor wafer W is generally obtained from the voltage V of the electromotive force output from the upper radiation thermometer 25 using the temperature conversion table 110. On the other hand, in the present embodiment, the temperature of the TC wafer 9 is converted into the voltage value using the voltage conversion table 120. The voltage conversion table 120 is stored in the storage of the controller 3, for example.

The controller 3 converts the temperature of the TC wafer 9 measured by the thermocouple in step S2 into the voltage value based on the voltage conversion table 120. For example, when the temperature of the TC wafer 9 measured by the thermocouple is 620° C., the voltage value is calculated from 620° C. as the measured temperature based on the equation (2) where the coefficient a is a7 and the constant b is b7. The voltage value obtained in step S3 is a theoretical voltage value calculated theoretically from the true temperature of the TC wafer 9 measured by the thermocouple based on the assumption that the measurement target is the black body.

On the other hand, an output value from the upper radiation thermometer 25 when the TC wafer 9 is measured by the upper radiation thermometer 25 is acquired (step S4). Specifically, the temperature of the TC wafer 9 increased during the soak period from the time t1 to the time t2 is measured by the upper radiation thermometer 25, and the voltage value output from the upper radiation thermometer 25 in this case is acquired. That is to say, steps S2 and S3 and step S4 are steps performed in parallel, and the temperature of the TC wafer 9 increased to the constant temperature is measured by both the thermocouple and the upper radiation thermometer 25. The voltage value acquired in step S4 is an actual voltage value actually measured by the upper radiation thermometer 25.

Next, the controller 3 calculates the emissivity based on the voltage value obtained in step S3 (theoretical voltage value) and the voltage value acquired in step S4 (actual voltage value) (step S5). Specifically, the controller 3 calculates emissivity F according to an equation (3):

$$\begin{matrix}[ Math 3 ] & \\ ε = \frac{Vr}{Vm} & ( 3 )\end{matrix}$$

In the equation (3), Vm is the theoretical voltage value obtained in step S3, and Vr is the actual voltage value acquired in step S4. The theoretical voltage value Vm and the actual voltage value Vr are values obtained by measuring the temperature of the TC wafer 9 increased to the constant temperature during the soak period respectively by the thermocouple and the upper radiation thermometer 25. A difference between the theoretical voltage value Vm and the actual voltage value Vr is made because, while the theoretical voltage value Vm is calculated based on the assumption that the measurement target is the black body (emissivity=1), the actual voltage value Vr is a value obtained by measuring the measurement target (TC wafer 9) that is actually not the black body (emissivity 1). True emissivity F can thus be obtained by dividing the actual voltage value Vr acquired in step S4 by the theoretical voltage value Vm calculated in step S3.

Next, the controller 3 determines whether the calculated emissivity F falls within a predetermined range set in advance (step S6). Specifically, an upper limit and a lower limit of true emissivity as assumed are set in advance and stored in the storage of the controller 3, for example. The controller 3 determines whether the emissivity F calculated in step S5 is a value between the upper limit and the lower limit.

When the calculated emissivity F falls outside the predetermined range, that is, when the calculated emissivity F exceeds the upper limit set in advance or falls below the lower limit set in advance, processing proceeds from step S6 to step S7, and the controller 3 issues an alarm. Specifically, the controller 3 displays a warning message on a display of the thermal processing apparatus 1, for example.

On the other hand, when the calculated emissivity F falls within the predetermined range, the controller 3 sets the calculated emissivity F for the upper radiation thermometer 25 (step S8). The controller 3 transmits, to the upper radiation thermometer 25, a command indicating that the calculated emissivity F is set, for example. When the command cannot be transmitted, it is determined that setting of the emissivity F has failed, processing proceeds from step S9 to step S10, and the controller 3 issues an alarm.

On the other hand, when the command can be transmitted to the upper radiation thermometer 25, it is determined that setting of the emissivity F has succeeded, processing proceeds from step S9 to step S11, and the TC wafer 9 is reheated. The TC wafer 9 is reheated also by irradiation with light from the halogen lamps HL. In this case, the controller 3 controls output of the halogen lamps HL according to the temperature adjustment recipe used in step S1 to reheat the TC wafer 9, for example. A pattern of a change in temperature of the TC wafer 9 during reheating is thus similar to that shown in FIG. 11.

The temperature of the TC wafer 9 is measured by the thermocouple during the soak period (period from the time t1 to the time t2 in FIG. 11) at reheating (step S12). Also in this case, as the value of the temperature of the TC wafer 9 measured by the thermocouple, the average value of the measured temperature in the two temperature measurement portions 96 is preferably used.

The temperature of the TC wafer 9 is also measured by the upper radiation thermometer 25 during the soak period at reheating (step S13). The emissivity F calculated in step S5 has been set for the upper radiation thermometer 25. The upper radiation thermometer 25 obtains, using the temperature conversion table 110 (FIG. 12), the temperature of the TC wafer 9 from the voltage of the electromotive force generated in the light-receiving element.

Next, the controller 3 determines whether a temperature deviation as a difference between the temperature of the TC wafer 9 measured by the thermocouple and the temperature of the TC wafer 9 measured by the upper radiation thermometer 25 is equal to or smaller than a predetermined threshold (step S14). That is to say, the temperature of the TC wafer 9 measured by the upper radiation thermometer 25 for which the above-mentioned emissivity F has been set is verified with reference to the true temperature of the TC wafer 9 measured by the thermocouple. As a result, when the temperature deviation exceeds a threshold, that is, when the temperature of the TC wafer 9 measured by the upper radiation thermometer 25 deviates from the temperature of the TC wafer 9 measured by the thermocouple by a certain temperature or more, processing proceeds from step S14 to step S15, and the controller 3 issues an alarm.

On the other hand, when the temperature deviation is equal to or smaller than the threshold, the temperature of the TC wafer 9 measured by the upper radiation thermometer 25 generally matches the true temperature of the TC wafer 9 measured by the thermocouple. In this case, correct emissivity F has been set for the upper radiation thermometer 25, so that a work on adjustment of the emissivity is completed (step S16).

In the present embodiment, the true temperature of the TC wafer 9 measured by the thermocouple is converted into the voltage value using the voltage conversion table 120. The emissivity is calculated based on the voltage value and the voltage value output from the upper radiation thermometer 25 when the TC wafer 9 is measured by the upper radiation thermometer 25, and the calculated emissivity is set for the upper radiation thermometer 25. The emissivity is calculated based on the voltage value obtained by conversion of the true temperature of the TC wafer 9 measured by the thermocouple, so that accurate emissivity can be obtained with high accuracy. The emissivity is calculated based on the voltage value obtained by direct conversion of the true temperature of the TC wafer 9 measured by the thermocouple using the voltage conversion table 120, so that accurate emissivity can be obtained in a short time as it is only required to perform less arithmetic processing of only heating the TC wafer 9 once. That is to say, according to the present embodiment, the emissivity set for the upper radiation thermometer 25 can rapidly be adjusted with high accuracy.

While the embodiment of the present invention has been described above, various changes other than those described above can be made without departing from the spirit of the present invention. For example, while the emissivity set for the upper radiation thermometer 25 is adjusted in the above-mentioned embodiment, the radiation thermometer for which the emissivity is set is not limited to the upper radiation thermometer 25, and technology according to the present invention is applicable to adjustment of the emissivity set for the lower radiation thermometer 20. That is to say, the emissivity set for the lower radiation thermometer 20 may be adjusted as in the above-mentioned embodiment.

Furthermore, when the calculated emissivity F falls outside the predetermined range in step S6 or when the temperature deviation exceeds the threshold in step S14, calculation of the emissivity in steps S1 to S5 may be repeated instead of (or in addition to) issuing the alarm.

Although the flash heating part 5 includes the 30 flash lamps FL in the above-mentioned embodiment, the number of flash lamps FL is not limited to 30 and may be any number. The flash lamps FL are not limited to the xenon flash lamps and may be krypton flash lamps. The number of halogen lamps HL of the halogen heating part 4 is also not limited to 40 and may be any number.

While the filament halogen lamps HL are used as continuous lighting lamps that emit light continuously for one second or more to perform preheating of the semiconductor wafer W in the above-mentioned embodiment, the lamps to perform preheating are not limited to the filament halogen lamps HL, and discharge arc lamps (e.g., xenon arc lamps) or LED lamps may be used as the continuous lighting lamps in place of the halogen lamps HL to perform preheating. In this case, the TC wafer 9 is to be heated by the arc lamps or the LED lamps.

### EXPLANATION OF REFERENCE SIGNS

1 thermal processing apparatus
3 controller
4 halogen heating part
5 flash heating part
6 chamber
7 holder
9 TC wafer
10 transfer mechanism
20 lower radiation thermometer
25 upper radiation thermometer
65 thermal processing space
74 susceptor
75 holding plate
78 opening
77 substrate support pin
110 temperature conversion table
120 voltage conversion table
FL flash lamp
HL halogen lamp
W semiconductor wafer

1. An emissivity adjustment method of adjusting emissivity set for a radiation thermometer installed in a thermal processing apparatus, the emissivity adjustment method comprising:
(a) heating a substrate with thermocouple to an increased temperature, the substrate with thermocouple including a thermocouple;
(b) measuring, by the thermocouple, the increased temperature of the substrate with thermocouple;
(c) calculating a theoretical voltage value from the temperature of the substrate with thermocouple measured by the thermocouple;
(d) measuring, by the radiation thermometer, the increased temperature of the substrate with thermocouple and outputting an actual voltage value from the radiation thermometer;
(e) calculating emissivity based on the theoretical voltage value and the actual voltage value; and
(f) setting the calculated emissivity for the radiation thermometer.

2. The emissivity adjustment method according to claim 1, wherein
a warning is issued when the calculated emissivity falls outside a predetermined range.

3. The emissivity adjustment method according to claim 1, further comprising:
(g) heating the substrate with thermocouple to an increased temperature; and
(h) verifying, with reference to a temperature of the substrate with thermocouple measured by the thermocouple, a temperature of the substrate with thermocouple measured by the radiation thermometer for which the emissivity has been set.

4. The emissivity adjustment method according to claim 3, wherein
a warning is issued when the temperature of the substrate with thermocouple measured by the radiation thermometer deviates from the temperature of the substrate with thermocouple measured by the thermocouple by a certain temperature or more.

5. The emissivity adjustment method according to claim 1, wherein
the theoretical voltage value is calculated based on a conversion table indicating a correlation between a voltage value output from the radiation thermometer and a temperature in (c).

6. The emissivity adjustment method according to claim 5, wherein
the conversion table indicates a correlation between a voltage value and a temperature when a black body is measured by the radiation thermometer.

7. The emissivity adjustment method according to claim 1, wherein
the substrate with thermocouple is heated by irradiation with light from a continuous lighting lamp and is maintained at a constant temperature in (a).
